(19) United States
(12) Patent Application Publication
(10) Pub. No.: US 2021/0373706 A1
(43) Pub. Date: Dec. 2, 2021

(54) ELECTROSTATIC SENSOR, CONTROL DEVICE, AND NON-TRANSITORY COMPUTER-READABLE MEDIUM

(71) Applicant: KABUSHIKI KAISHA TOKAI RIKA DENKI SEISAKUSHO, Aichi (JP)

(72) Inventors: Takao IMAI, Aichi (JP); Katsuhiro TSUCHIYA, Aichi (JP)

(73) Assignee: KABUSHIKI KAISHA TOKAI RIKA DENKI SEISAKUSHO, Aichi (JP)

(21) Appl. No.: 17/329,518

(22) Filed: May 25, 2021

(30) Foreign Application Priority Data
Jun. 1, 2020 (JP) 2020-095691

(51) Int. Cl. G06F 3/044

(52) U.S. Cl. CPC G06F 3/0443; G06F 3/04164; G06F 3/0444

(57) ABSTRACT

A detection device is configured to detect an electrostatic capacitance between an operated member having a plurality of detection areas and an electrode having areas associated with the detection areas respectively. A control device is configured to determine whether an operation is performed to each of the detection areas based on whether the electrostatic capacitance exceeds a threshold value. At least one of the detection areas has a first area and a second area. The second area is located between the first area and another one of the detection areas. The control device determines that an operation is not performed to the at least one detection area having the first area and the second area in a case where the electrostatic capacitance detected for the second area exceeds the threshold value.

### FIELD

The presently disclosed subject matter relates to an electrostatic sensor equipped with an operated member (a member to be operated) having a plurality of detection areas. The presently disclosed subject matter also relates to a control device configured to control an operation of the electrostatic sensor, as well as a non-transitory computer-readable medium having stored a computer program adapted to be executed by a processor of the control device.

### BACKGROUND

Japanese Patent Publication No. 2015-210811A discloses an electrostatic sensor. In the electrostatic sensor, a pseudo capacitor is formed by an approach of a finger or the like of a user to an operated member located in an electric field generated by an electrode, so that an electrostatic capacitance between the electrode and the operated member is increased. When the increase in the electrostatic capacitance is detected, it is determined whether an operation with respect to the operated member is performed by the user.

### SUMMARY

### Technical Problem

It is demanded to improve the operability of an electrostatic sensor equipped with an operated member having a plurality of detection areas.

### Solution to Problem

In order to meet the demand described above, a first illustrative aspect of the presently disclosed subject matter provides an electrostatic sensor, comprising:

a detection device configured to detect an electrostatic capacitance between an operated member having a plurality of detection areas and an electrode having areas associated with the detection areas respectively; and

a control device configured to determine whether an operation is performed to each of the detection areas based on whether the electrostatic capacitance exceeds a threshold value,

wherein at least one of the detection areas has a first area and a second area;

wherein the second area is located between the first area and another one of the detection areas; and

wherein the control device determines that an operation is not performed to the at least one detection area having the first area and the second area in a case where the electrostatic capacitance detected for the second area exceeds the threshold value.

In order to meet the demand described above, a second illustrative aspect of the presently disclosed subject matter provides a control device configured to control an operation of an electrostatic sensor equipped with an operated member having a plurality of detection areas, comprising:

a reception interface configured to receive detection information corresponding to an electrostatic capacitance between the operated member and an electrode having areas associated with the detection areas respectively; and

a processor configured to determine whether an operation is performed to each of the detection areas based on whether the electrostatic capacitance exceeds a threshold value,

wherein at least one of the detection areas has a first area and a second area;

wherein the second area is located between the first area and another one of the detection areas; and

wherein the processor determines that an operation is not performed to the at least one detection area having the first area and the second area in a case where the electrostatic capacitance detected for the second area exceeds the threshold value.

In order to meet the demand described above, a third illustrative aspect of the presently disclosed subject matter provides a non-transitory computer-readable medium having stored a computer program adapted to be executed by a processor of a control device configured to control an operation of an electrostatic sensor equipped with an operated member having a plurality of detection areas, wherein at least one of the detection areas has a first area and a second area, and wherein the second area is located between the first area and another one of the detection areas, the computer program is configured to cause, when executed, the control device to:

receive detection information corresponding to an electrostatic capacitance between the operated member and an electrode having areas associated with the detection areas respectively;

determine whether an operation is performed to each of the detection areas based on whether the electrostatic capacitance exceeds a threshold value; and

determine that an operation is not performed to the at least one detection area having the first area and the second area in a case where the electrostatic capacitance detected for the second area exceeds the threshold value.

With the configuration according to each of the first to third illustrative aspects, for a detection area having the first area and the second area among the detection areas, even if the electrostatic capacitance between the operated member and the electrode associated with the second area disposed between the first area and another detection area exceeds the threshold value, it is not determined that the operation is performed to the detection area. Accordingly, even if an operating item unintentionally contacts or approaches the detection area having the first area while the operating item is being performed with respect to another detection area, since it accompanies contact or approach with respect to the second area, it is possible to suppress the occurrence of a situation that the contact or approach is detected as an operation with respect to the detection area having the first area. Accordingly, it is possible to improve the operability of the electrostatic sensor equipped with the operated member having a plurality of detection areas.

In order to meet the demand described above, a fourth illustrative aspect of the presently disclosed subject matter provides an electrostatic sensor, comprising:

a detection device configured to detect an electrostatic capacitance between an operated member having a plurality of detection areas and an electrode having areas associated with the detection areas respectively; and

a control device configured to determine whether an operation is performed to each of the detection areas based on whether the electrostatic capacitance exceeds a threshold value,

wherein at least one of the detection areas has a first area and a second area;

wherein the second area is located between the first area and another one of the detection areas; and

wherein the control device determines that an operation is performed to the at least one detection area having the first area and the second area in a case where the electrostatic capacitance detected for the first area exceeds the threshold value.

In order to meet the demand described above, a fifth illustrative aspect of the presently disclosed subject matter provides a control device configured to control an operation of an electrostatic sensor equipped with an operated member having a plurality of detection areas, comprising:

a reception interface configured to receive detection information corresponding to an electrostatic capacitance between the operated member and an electrode having areas associated with the detection areas respectively; and

a processor configured to determine whether an operation is performed to each of the detection areas based on whether the electrostatic capacitance exceeds a threshold value,

wherein at least one of the detection areas has a first area and a second area;

wherein the second area is located between the first area and another one of the detection areas; and

wherein the processor determines that an operation is performed to the at least one detection area having the first area and the second area in a case where the electrostatic capacitance detected for the first area exceeds the threshold value.

In order to meet the demand described above, a sixth illustrative aspect of the presently disclosed subject matter provides a non-transitory computer-readable medium having stored a computer program adapted to be executed by a processor of a control device configured to control an operation of an electrostatic sensor equipped with an operated member having a plurality of detection areas, wherein at least one of the detection areas has a first area and a second area, and wherein the second area is located between the first area and another one of the detection areas, the computer program is configured to cause, when executed, the control device to:

receive detection information corresponding to an electrostatic capacitance between the operated member and an electrode having areas associated with the detection areas respectively;

determine whether an operation is performed to each of the detection areas based on whether the electrostatic capacitance exceeds a threshold value; and

determine that an operation is performed to the at least one detection area having the first area and the second area in a case where the electrostatic capacitance detected for the first area exceeds the threshold value.

With the configuration according to each of the fourth to sixth illustrative aspects, for a detection area having the first area and the second area among the detection areas, when the electrostatic capacitance between the operated member and the electrode associated with the first area sandwiching the second area with another detection area exceeds the threshold value, it is determined that the operation is performed to the detection area. When an operating item contacts or approaches a plurality of detection areas unintentionally, it accompanies contact or approach to the second area. Accordingly, when contact or approach to the first area is detected, there is a high possibility that an intentional operation is performed to a detection area having the first area. Accordingly, since an accurate detection of an operation performed to the detection area having the first area can be made easier, it is possible to improve the operability of the electrostatic sensor equipped with the operated member having a plurality of detection areas.

In order to meet the demand described above, a seventh illustrative aspect of the presently disclosed subject matter provides an electrostatic sensor, comprising:

a detection device configured to detect an electrostatic capacitance between an operated member having a plurality of detection areas and an electrode having areas associated with the detection areas respectively; and

a control device configured to determine whether an operation is performed to each of the detection areas based on whether the electrostatic capacitance exceeds a threshold value,

wherein the detection device detects contact or approach of an operating item with respect to a detection electrode located between the contact areas; and

wherein the control device determines that an operation is not performed to the operated member in a case where the contact or approach of the operating item with respect to the detection electrode is detected.

In order to meet the demand described above, an eighth illustrative aspect of the presently disclosed subject matter provides a control device configured to control an operation of an electrostatic sensor equipped with an operated member having a plurality of detection areas, comprising:

a reception interface configured to receive first detection information corresponding to an electrostatic capacitance between the operated member and an electrode having areas associated with the detection areas respectively; and

a processor configured to determine whether an operation is performed to each of the detection areas based on whether the electrostatic capacitance corresponding to the first detection information exceeds a threshold value,

wherein the reception interface receives second detection information indicative of contact or approach of an operating item with respect to a detection electrode located between the contact areas; and

wherein the processor determines that an operation is not performed to the operated member in a case where the reception interface receives the second detection information.

In order to meet the demand described above, a ninth illustrative aspect of the presently disclosed subject matter provides a non-transitory computer-readable medium having stored a computer program adapted to be executed by a processor of a control device configured to control an operation of an electrostatic sensor equipped with an operated member having a plurality of detection areas, the computer program is configured to cause, when executed, the control device to:

receive first detection information corresponding to an electrostatic capacitance between the operated member and an electrode having areas associated with the detection areas respectively;

receive second detection information indicative of contact or approach of an operating item with respect to a detection electrode located between the contact areas;

determine whether an operation is performed to each of the detection areas based on whether the electrostatic capacitance corresponding to the first detection information exceeds a threshold value; and

determine that an operation is not performed to the operated member in a case where the reception interface receives the second detection information.

With the configuration according to each of the seventh to ninth illustrative aspects, even if the electrostatic capacitance between the operated member and the electrode associated with one of the detection areas exceeds the threshold value, it is not determined that the operation is performed to the operated member as long as contact or approach of an operating item with respect to the detection electrode disposed between the detection areas is detected. When an operating item performing an operation with respect to one detection area unintentionally contacts or approaches another detection area, it accompanies contact or approach with respect to the detection electrode. Accordingly, it is possible to suppress the occurrence of a situation that the contact or approach is detected as an operation with respect to another detection area. Accordingly, it is possible to improve the operability of the electrostatic sensor equipped with the operated member having a plurality of detection areas.

### BRIEF DESCRIPTION OF DRAWINGS

FIG. 1 illustrates a configuration of an electrostatic sensor according to a first embodiment.

FIG. 2 illustrates a vehicle in which the electrostatic sensor of FIG. 1 is to be installed.

FIG. 3 illustrates a flow of processing executed by a control device of FIG. 1.

FIG. 4 illustrates an exemplary operation of the electrostatic sensor of FIG. 1.

FIG. 5 illustrates an exemplary operation of the electrostatic sensor of FIG. 1.

FIG. 6 illustrates a configuration of an electrostatic sensor according to a second embodiment.

FIG. 7 illustrates a flow of processing executed by a control device of FIG. 6.

FIG. 8 illustrates an exemplary operation of the electrostatic sensor of FIG. 6.

FIG. 9 illustrates an exemplary operation of the electrostatic sensor of FIG. 6.

### DESCRIPTION OF EMBODIMENTS

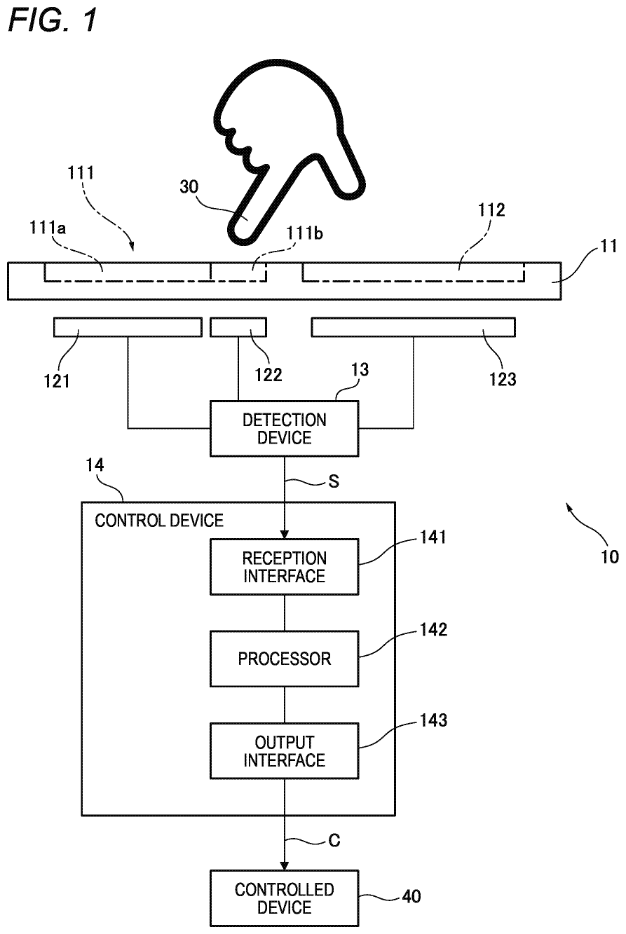

Examples of embodiments will be described in detail below with reference to the accompanying drawings. FIG. 1 illustrates a functional configuration of an electrostatic sensor 10 according to a first embodiment.

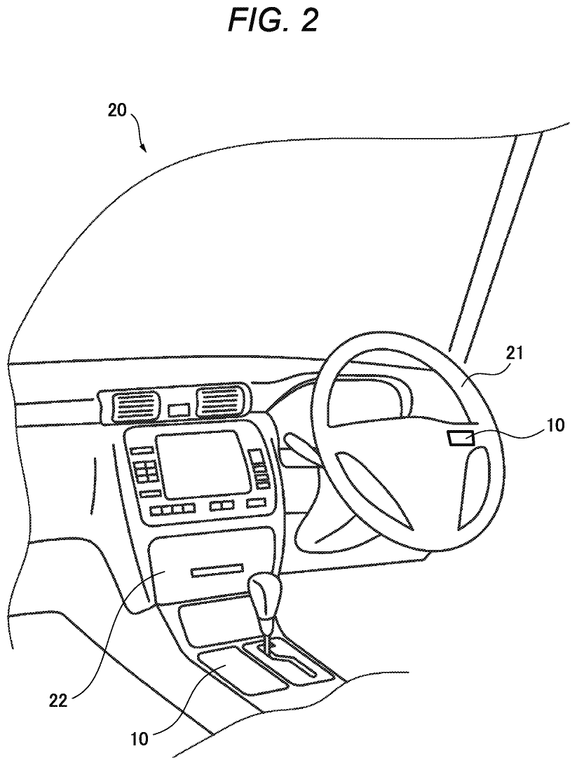

As illustrated in FIG. 2, the electrostatic sensor 10 is configured to be installed in a vehicle 20. For example, the electrostatic sensor 10 may be disposed on a steering wheel 21 or a center cluster 22 in a vehicle cabin of the vehicle 20. The electrostatic sensor 10 is configured to accept an operation performed by an occupant of the vehicle 20, and to remotely operate a controlled device installed in the vehicle 20 based on the operation. Examples of the controlled device include an air conditioner, a lighting device, an audio-visual equipment, a power windows driving device, and a seat control device. The vehicle 20 is an example of a mobile entity.

As illustrated in FIG. 1, the electrostatic sensor 10 includes an operated member 11. The operated member 11 is configured to accept an operation performed with a finger 30 of an occupant of the vehicle 20.

The operated member 11 has a first detection area 111 and a second detection area 112 on its surface. Each of the first detection area 111 and the second detection area 112 is an area capable of accepting an operation performed with the finger 30 for enabling a specific function of the controlled device 40. These areas are not structurally partitioned by the formation of grooves or steps on the surface, but at least one of a differently-colored portion, a mark, and an unevenness each of which has a small influence on the operation is appropriately provided on the surface, thereby causing the occupant to recognize the position of each area. In this example, the first detection area 111 and the second detection area 112 are adjacent to each other.

The first detection area 111 includes a main area 111a and a sub area 111b. The sub area 111b is disposed between the main area 111a and the second detection area 112. The main area 111a is an example of a first area. The sub area 111b is an example of a second area.

The electrostatic sensor 10 includes a first electrode 121, a second electrode 122, and a third electrode 123. The first electrode 121 has an area associated with the main area 111a in the first detection area 111 of the operated member 11. The second electrode 122 has an area associated with the sub area 111b in the first detection area 111 of the operated member 11. The third electrode 123 has an area associated with the second detection area 112 of the operated member 11.

The electrostatic sensor 10 includes a detection device 13. The detection device 13 is configured to detect an electrostatic capacitance between the operated member 11 and the first electrode 121, an electrostatic capacitance between the operated member 11 and the second electrode 122, as well as an electrostatic capacitance between the operated member 11 and the third electrode 123, respectively.

Specifically, the detection device 13 includes a charging/discharging circuit. The charging/discharging circuit can perform a charging operation and a discharging operation. The charging/discharging circuit during the charging operation supplies current supplied from a power source (not illustrated) to the first electrode 121, the second electrode 122, and the third electrode 123. The charging/discharging circuit during the discharging operation causes each electrode to emit current. An electric field is generated around the operated member 11 by the current supplied to each electrode. As the finger 30 approaches this electric field, a pseudo capacitor is formed between a particular electrode and the finger 30. As a result, the electrostatic capacitance between the specific electrode and the operated member 11 is increased. As the electrostatic capacitance increases, the current emitted from the particular electrode during the discharging operation increases.

That is, the detection device 13 can detect a position in the operated member 11 where the finger 30 approaches or contacts by detecting the electrostatic capacitance between the operated member 11 and each electrode. The detection device 13 is configured to output detection information S indicating a position in the operated member 11 where the finger 30 approaches or contacts. The detection information S may be in the form of analog data or may be in the form of digital data.

The electrostatic sensor 10 includes a control device 14. The control device 14 includes a reception interface 141, a processor 142, and an output interface 143.

The reception interface 141 is configured as an interface for receiving the detection information S outputted from the detection device 13. In a case where the detection information S is in the form of analog data, the reception interface 141 is configured to be equipped with an appropriate conversion circuit including an A/D converter.

As described above, the detection information S may indicate the position in the operated member 11 where the finger 30 approaches or contacts. The processor 142 is configured to determine that the finger 30 contacts or approaches the first detection area 111 or the second detection area 112 in the operated member 11 based on the detection information S.

The output interface 143 is configured as an interface for outputting control information C for controlling the operation of the controlled device 40. The processor 142 is configured to output the control information C from the output interface 143 based on the position in the operated member 11 at which the contact or approach of the finger 30 is detected. The control information C may be in the form of analog data or may be in the form of digital data. In a case where the control information C is in the form of analog data, the output interface 143 is configured to be equipped with an appropriate conversion circuit including a D/A converter.

For example, when it is detected that the finger 30 contacts or approaches the second detection area 112 based on the detection information S, the processor 142 outputs control information C for enabling one function of the controlled device 40 from the output interface 143.

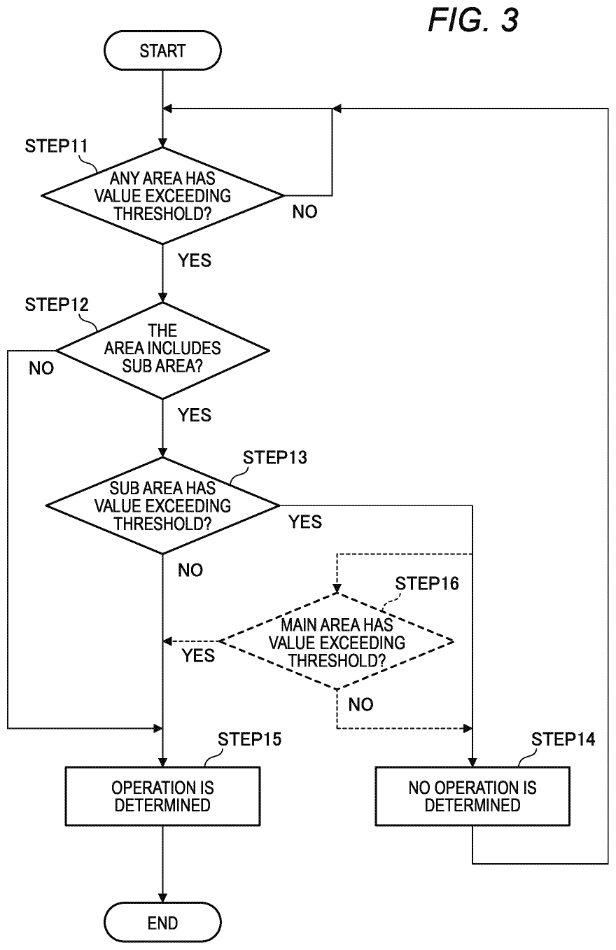

Referring to FIG. 3, a more specific flow of processing executed by the processor 142 of the control device 14 will be described.

Based on the detection information S, the processor 142 determines whether there is a detection area associated with an electrode whose electrostatic capacitance with respect to the operated member 11 detected by the detection device 13 exceeds a threshold value (STEP11). The determination is repeated until a corresponding detection area is found (NO in STEP11).

When it is determined that there is a detection area associated with an electrode whose electrostatic capacitance with respect to the operated member 11 exceeds the threshold value (YES in STEP11), the processor 142 determines whether the detection area includes a sub area (STEP12). In this example, it is determined whether the detection area is the first detection area 111 having the sub area 111b.

When it is determined that the detection area is the first detection area 111 including the sub area 111b (YES in STEP12), the processor 142 determines whether the electrostatic capacitance between the second electrode 122 associated with the sub area 111b and the operated member 11 exceeds a threshold value (STEP13).

When it is determined that the electrostatic capacitance between the second electrode 122 associated with the sub area 111b and the operated member 11 exceeds the threshold value (YES in STEP13), the processor 142 determines that no operation is performed to the first detection area 111 (STEP14). Thereafter, the processing returns to STEP11.

When it is determined that the electrostatic capacitance between the second electrode 122 associated with the sub area 111b and the operated member 11 does not exceed the threshold value (NO in STEP13), in other words, when it is determined that the electrostatic capacitance between the first electrode 121 associated with the main area 111a and the operated member 11 exceeds the threshold value, the processor 142 determines that an operation is performed to the first detection area 111 (STEP15). Thereafter, the processing ends.

When it is determined that the detection area associated with the electrode whose electrostatic capacitance with respect to the operated member 11 exceeds the threshold value is a detection area not including the sub area 111b (NO in STEP12), the processor 142 determines that the operation is performed to the detection area (STEP15). In this example, it is determined that the operation is performed to the second detection area 112. Thereafter, the processing ends.

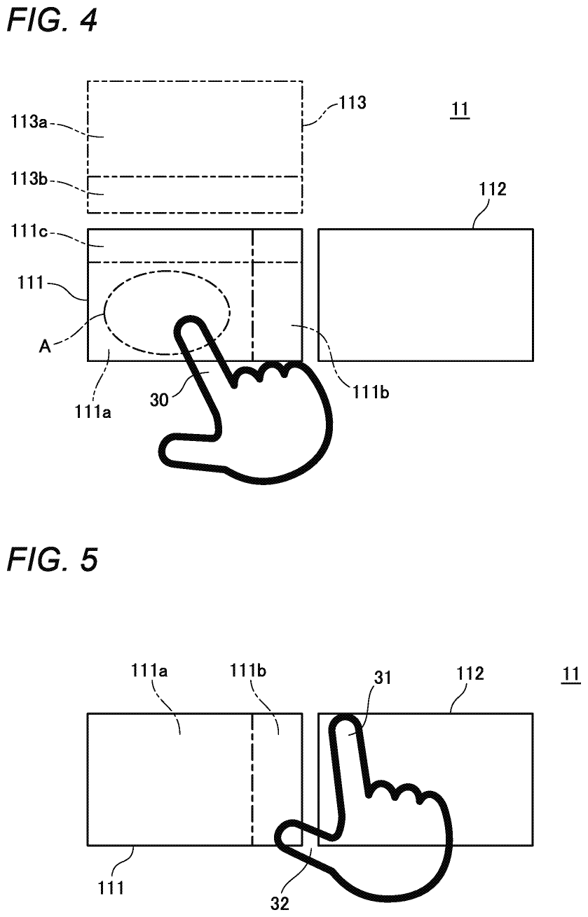

Referring to FIGS. 4 and 5, an exemplary operation of the electrostatic sensor 10 configured as described above will be described. In FIG. 4, the finger 30 of the user contacts only the main area 111a of the first detection area 111 of the operated member 11.

In this case, the electrostatic capacitance between the first electrode 121 associated with the main area 111a and the operated member 11 exceeds the threshold value (YES in STEP11 and YES in STEP12 in FIG. 3). On the other hand, the electrostatic capacitance between the first electrode 121 associated with the sub area 111b and the operated member 11 does not exceed the threshold value (NO in STEP13 in FIG. 3). Accordingly, the processor 142 of the control device 14 determines that the operation is performed to the first detection area 111 (STEP15 in FIG. 3).

In FIG. 5, a finger 31 of the user contacts the second detection area 112 of the operated member 11, and another finger 32 of the user contacts the sub area 111b of the first detection area 111 of the operated member 11.

In this case, the electrostatic capacitance between the third electrode 123 associated with the second detection area 112 and the operated member 11 exceeds the threshold value (YES in STEP11 in FIG. 3). Since the second detection area 112 does not have a sub area (NO in STEP12 in FIG. 3), the processor 142 of the control device 14 determines that the operation is performed to the second detection area 112 (STEP15 in FIG. 3).

On the other hand, the electrostatic capacitance between the second electrode 122 associated with the sub area 111b of the first detection area 111 and the operated member 11 exceeds the threshold value (YES in STEP11, YES in STEP12, and YES in STEP13 in FIG. 3). Accordingly, the processor 142 of the control device 14 determines that no operation is performed to the first detection area 111 (STEP14 in FIG. 3).

According to the configuration as described above, for the first detection area 111 having the sub area 111b that is located between the main area 111a and the second detection area 112, even if the electrostatic capacitance between the second electrode 122 associated with the sub area 111b and the operated member 11 exceeds the threshold value, it is not determined that the operation is performed to the first detection area 111. As a result, when an occupant performs an operation to the second detection area 112, even if a part of the occupant's body contacts or approaches the first detection area 111 unintentionally, it is possible to suppress an occurrence of a situation that the contact or approach is detected as an operation to the first detection area 111. Accordingly, it is possible to improve the operability of the electrostatic sensor equipped with the operated member having a plurality of detection areas.

As illustrated in FIG. 3, when it is determined that the electrostatic capacitance between the second electrode 122 associated with the sub area 111b and the operated member 11 exceeds the threshold value (YES in STEP13), the processor 142 may determine whether the electrostatic capacitance between the first electrode 121 associated with the main area 111a and the operated member 11 exceeds the threshold value (STEP16).

When it is determined that the electrostatic capacitance between the first electrode 121 and the operated member 11 associated with the main area 111a does not exceed the threshold value (NO in STEP16), the processor 142 determines that no operation is performed to the first detection area 111 (STEP14). Thereafter, the processing returns to STEP11.

When it is determined that the electrostatic capacitance between the first electrode 121 associated with the main area 111a and the operated member 11 exceeds the threshold value (YES in STEP16), the processor 142 determines that an operation is performed to the first detection area 111 (STEP15). Thereafter, the processing ends.

That is, even if the electrostatic capacitance between the second electrode 122 associated with the sub area 111b and the operated member 11 exceeds the threshold value, it is determined that there is a high possibility that the first detection area 111 is intentionally operated as long as the electrostatic capacitance between the first electrode 121 associated with the main area 111a and the operated member 11 exceeds the threshold value. According to such a configuration, it is possible to easily distinguish a case where an intentional operation is performed to the first detection area 111 from a case where an unintentional operation is performed to the first detection area 111. Since the frequency with which it is determined that no operation is performed to the first detection area 111 is reduced, it is possible to improve the operability of the electrostatic sensor equipped with the operated member having a plurality of detection areas.

Instead of the processing in STEP13 in FIG. 3, the processor 142 may perform only the processing in STEP16. That is, the processor 142 may determine that the operation is performed to the first detection area 111 when the electrostatic capacitance between the first electrode 121 associated with the main area 111a and the operated member 11 exceeds the threshold value, and may determine that the operation is not performed to the first detection area 111 when the electrostatic capacitance does not exceed the threshold value.

When the finger 30 contacts or approaches both the first detection area 111 and the second detection area 112 unintentionally, it accompanies contact or approach to the sub area 111b. Accordingly, when contact or approach to the main area 111a is detected, there is a high possibility that an intentional operation is performed to the first detection area 111. According to such a configuration, since an accurate detection of an operation performed to the first detection area 111 can be made easier, it is possible to improve the operability of the electrostatic sensor equipped with the operated member having a plurality of detection areas.

As illustrated in FIG. 4, a size of the main area 111a is larger than a size of the sub area 111b.

According to such a configuration, even if it is possible to suppress the occurrence of a situation that an operation performed to the first detection area 111 is made due to unintentional contact or approach of a part of the user's body to the first detection area 111, it is also possible to suppress the degradation of the operability with respect to the first detection area 111. This advantage becomes more remarkable as at least one of the size of each detection area and the distance between the adjacent detection areas becomes smaller.

The processor 142 having each function described above can be implemented by a general-purpose microprocessor operating in cooperation with a general-purpose memory. Examples of the general-purpose microprocessor include a CPU, an MPU, and a GPU. Examples of the general-purpose memory include a ROM and a RAM. In this case, a computer program for executing the above-described processing can be stored in the ROM. The ROM is an example of a non-transitory computer-readable medium having recorded a computer program. The general-purpose microprocessor designates at least a part of the program stored in the ROM, loads the program on the RAM, and executes the processing described above in cooperation with the RAM. The above-mentioned computer program may be pre-installed in a general-purpose memory, or may be downloaded from an external server via a communication network and then installed in the general-purpose memory. In this case, the external server is an example of the non-transitory computer-readable medium having stored a computer program.

The processor 142 may be implemented by a dedicated integrated circuit capable of executing the above-described computer program, such as a microcontroller, an ASIC, and an FPGA. In this case, the above-described computer program is pre-installed in the storage element included in the dedicated integrated circuit. The memory element is an example of a non-transitory computer-readable medium in which a computer program is stored. The processor 142 may also be implemented by a combination of a general-purpose microprocessor and a dedicated integrated circuit.

The above embodiments are merely illustrative for facilitating understanding of the presently disclosed subject matter. The configuration according to the above embodiment can be appropriately modified or improved without departing from the gist of the presently disclosed subject matter.

In the above embodiment, the operated member 11 has two detection areas. However, the number of the detection areas may be three or more. The position, shape, size, and type of operation that can be accepted of each detection area in the operated member 11 can be appropriately determined according to the function of the controlled device 40 to be controlled.

As an example, as illustrated in FIG. 4, the operated member 11 may have a third detection area 113. The third detection area 113 is adjacent to the first detection area 111. In this case, the first detection area 111 may have a sub area 111c. The sub area 111c is disposed between the main area 111a and the third detection area 113. Additionally or alternatively, the third detection area 113 may include a main area 113a and a sub area 113b. In this case, the sub area 113b is disposed between the main area 113a and the first detection area 111. The processing described with reference to the sub area 111b can be applied to the sub area 111c and the sub area 113b as well. Each of the sub area 111c and the sub area 113b is an example of the second area.

In the above embodiment, the absolute value of the detected electrostatic capacitance is used for comparison with the threshold value in order to determine whether an operation is performed to the detection area of the operated member 11. However, the determination as to whether the operation with respect to the detection area is performed may be made based on an amount of change from a reference electrostatic capacitance that can be constantly changed according to the state of the operated member 11. In this case, a threshold value defined for the amount of change is used.

In the above embodiment, the electrostatic capacitance between the operated member 11 and the finger 30 of the occupant is detected. As long as a change in the electrostatic capacitance caused by an operation performed to the operated member 11 can be detected, the operation may be performed with another body part, or with clothing or a tool interposed between the body part and the operated member 11.

In this case, as illustrated in FIG. 4, it is preferable that the size of the main area 111a of the first detection area 111 be larger than a contact area A assumed for an operating item such as the finger 30 that performs an operation with respect to the operated member 11. According to such a configuration, even if it is possible to suppress the occurrence of a situation that an operation performed to the first detection area 111 is made due to unintentional contact or approach of the operating item to the first detection area 111, it is also possible to suppress the degradation of the operability with respect to the first detection area 111. This advantage becomes more remarkable as at least one of the size of each detection area and the distance between the adjacent detection areas becomes smaller.

The electrostatic sensor 10 may be installed in a mobile entity other than the vehicle 20. Examples of the mobile entity include railways, aircrafts, and ships. The mobile entity may not require a driver. The electrostatic sensor 10 may be installed in a mobile device capable of being carried by a user. A mobile device is also an example of the mobile entity. When the electrostatic sensor 10 is provided in such a mobile entity, a part of the user's body tends to contact or approach an unintended detection area due to the movement or vibration of the mobile entity. Accordingly, the utility of the electrostatic sensor 10 having the configuration as described above is further enhanced.

The electrostatic sensor 10 need not be installed in a mobile entity. As long as the operation of the controlled device 40 can be controlled through an operation performed to the operated member 11, the illustrated configuration can be applied to any application, such as a stationary device, a building such as a house or a facility.

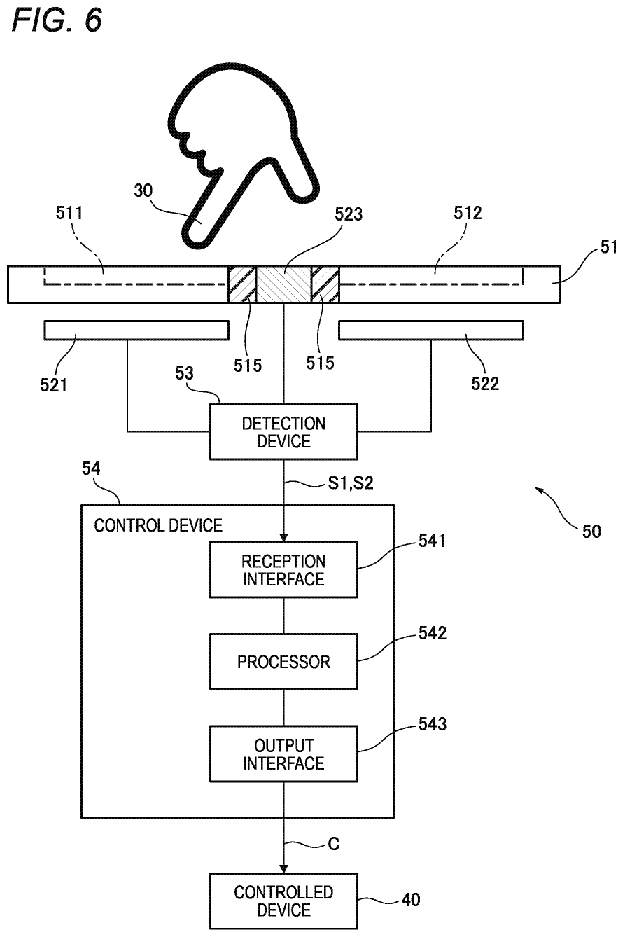

FIG. 6 illustrates a functional configuration of an electrostatic sensor 50 according to a second embodiment. The electrostatic sensor 50 is configured to be installed in the vehicle 20 illustrated in FIG. 2 similarly to the electrostatic sensor 10 according to the first embodiment.

As illustrated in FIG. 6, the electrostatic sensor 50 includes an operated member 51. The operated member 51 is configured to accept an operation performed with a finger 30 of an occupant of the vehicle 20. The finger 30 is an example of an operating item.

The operated member 51 has a first detection area 511 and a second detection area 512 on its surface. Each of the first detection area 511 and the second detection area 512 is an area capable of accepting an operation performed with the finger 30 for enabling a specific function of the controlled device 40. In this example, the first detection area 511 and the second detection area 512 are adjacent to each other.

The electrostatic sensor 50 includes a first electrode 521 and a second electrode 522. The first electrode 521 has an area associated with the first detection area 511 of the operated member 51. The second electrode 522 has an area associated with the second detection area 512 of the operated member 51.

The electrostatic sensor 50 includes a detection device 53. The detection device 53 is configured to detect an electrostatic capacitance between the operated member 51 and the first electrode 521, and an electrostatic capacitance between the operated member 51 and the second electrode 522, respectively.

Specifically, the detection device 53 includes a charging/discharging circuit. The charging/discharging circuit can perform a charging operation and a discharging operation. The charging/discharging circuit during the charging operation supplies current supplied from a power source (not illustrated) to the first electrode 521 and the second electrode 522. The charging/discharging circuit during the discharging operation causes each electrode to emit current. An electric field is generated around the operated member 51 by the current supplied to each electrode. As the finger 30 approaches this electric field, a pseudo capacitor is formed between a particular electrode and the finger 30. As a result, the electrostatic capacitance between the specific electrode and the operated member 51 is increased. As the electrostatic capacitance increases, the current emitted from the particular electrode during the discharging operation increases.

That is, the detection device 53 can detect a position in the operated member 51 where the finger 30 approaches or contacts by detecting the electrostatic capacitance between the operated member 51 and each electrode. The detection device 53 is configured to output first detection information 51 indicating a position in the operated member 51 where the finger 30 approaches or contacts. The first detection information 51 may be in the form of analog data or may be in the form of digital data.

The electrostatic sensor 50 includes a control device 54. The control device 54 includes a reception interface 541, a processor 542, and an output interface 543.

The reception interface 541 is configured as an interface for receiving the first detection information S1 outputted from the detection device 53. In a case where the first detection information S1 is in the form of analog data, the reception interface 541 is configured to be equipped with an appropriate conversion circuit including an A/D converter.

As described above, the first detection information S1 may indicate the position in the operated member 51 where the finger 30 approaches or contacts. The processor 542 is configured to determine that the finger 30 contacts or approaches the first detection area 511 or the second detection area 512 in the operated member 51 based on the first detection information S1.

The output interface 543 is configured as an interface for outputting control information C for controlling the operation of the controlled device 40. The processor 542 is configured to output the control information C from the output interface 543 based on the position in the operated member 51 at which the contact or approach of the finger 30 is detected. The control information C may be in the form of analog data or may be in the form of digital data. In a case where the control information C is in the form of analog data, the output interface 543 is configured to be equipped with an appropriate conversion circuit including a D/A converter.

For example, when it is detected that the finger 30 contacts or approaches the second detection area 512 based on the first detection information S1, the processor 542 outputs control information C for enabling one function of the controlled device 40 from the output interface 543.

The electrostatic sensor 50 includes a detection electrode 523. The detection electrode 523 is disposed between the first detection area 511 and the second detection area 512 in the operated member 51. The detection device 53 is configured to output second detection information S2 indicating that the finger 30 contacts or approaches the detection electrode 523. The second detection information S2 may be in the form of analog data or may be in the form of digital data. The contact or approach of the finger 30 with respect to the detection electrode 523 can be detected by a well-known technique based on a change in an electrical property (a potential, a current, a resistance value, or the like) in connection with the detection electrode 523.

The reception interface 541 is configured as an interface for receiving the second detection information S2 outputted from the detection device 53 as well. In a case where the second detection information S2 is in the form of analog data, the reception interface 541 is configured to be equipped with an appropriate conversion circuit including an A/D converter.

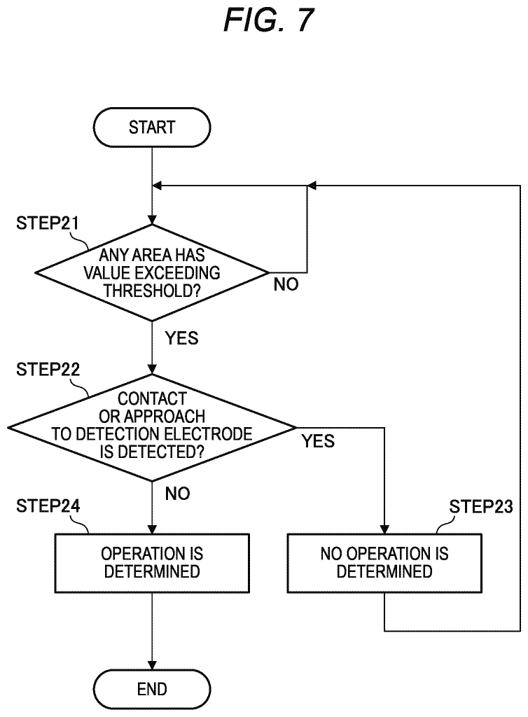

Referring to FIG. 7, a more specific flow of processing executed by the processor 542 of the control device 54 will be described.

Based on the first detection information S 1, the processor 542 determines whether there is a detection area associated with an electrode whose electrostatic capacitance with the operated member 51 detected by the detection device 53 exceeds a threshold value (STEP21). The determination is repeated until a corresponding detection area is found (NO in STEP21).

When it is determined that there is a detection area associated with an electrode whose electrostatic capacitance with respect to the operated member 51 exceeds the threshold value (YES in STEP21), the processor 542 determines whether the finger 30 contacts or approaches the detection electrode 523 based on the second detection information S2 (STEP22).

When it is determined that the finger 30 contacts or approaches the detection electrode 523 (YES in STEP22), the processor 542 determines that no operation is performed to the detection area (STEP23). Thereafter, the processing returns to STEP21.

When it is determined that the finger 30 does not contact or approach the detection electrode 523 (NO in STEP22), the processor 542 determines that the operation is performed to the detection area (STEP24). Thereafter, the processing ends.

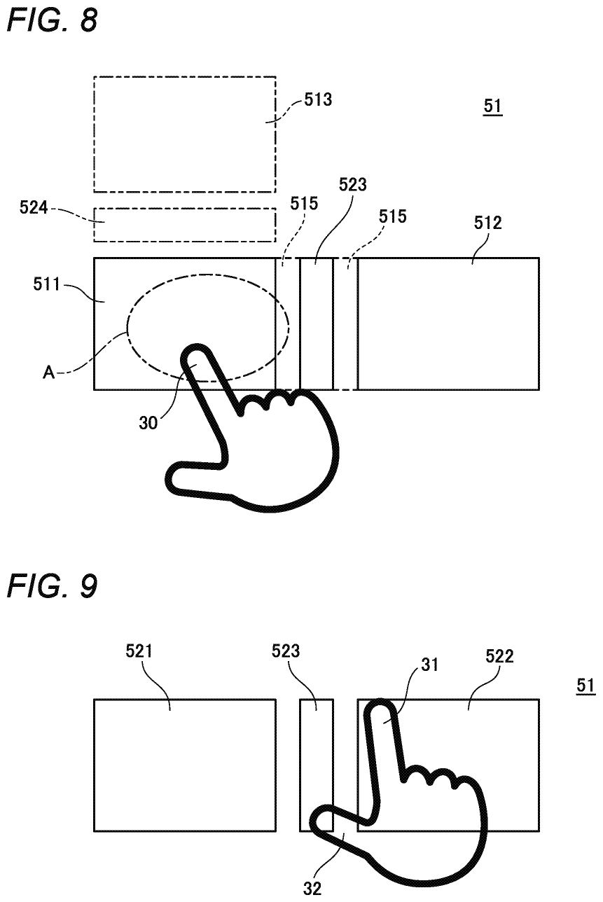

Referring to FIGS. 8 and 9, an exemplary operation of the electrostatic sensor 50 configured as described above will be described. In FIG. 8, the finger 30 of the user contacts only the first detection area 511 of the operated member 51.

In this case, the electrostatic capacitance between the first electrode 521 associated with the first detection area 511 and the operated member 51 exceeds the threshold value (YES in STEP21 in FIG. 7). On the other hand, the contact or approach of the finger 30 with respect to the detection electrode 523 is not detected (NO in STEP22 in FIG. 7). Accordingly, the processor 542 of the control device 54 determines that the operation is performed to the first detection area 511 (STEP24 in FIG. 7).

In FIG. 9, a finger 31 of the user contacts the second detection area 512 of the operated member 51, and another finger 32 of the user contacts the detection electrode 523.

In this case, the electrostatic capacitance between the second electrode 522 associated with the second detection area 512 and the operated member 51 exceeds the threshold value (YES in STEP21 in FIG. 7). However, since the contact of the finger 32 with respect to the detection electrode 523 is detected (YES in STEP22 in FIG. 7), the processor 542 of the control device 54 determines that no operation is performed to the second detection area 512 (STEP23 in FIG. 7).

According to the configuration as described above, even if the electrostatic capacitance between the operated member 51 and any of the first electrode 521 associated with the first detection area 511 and the second electrode 522 associated with the second detection area 512 exceeds the threshold value, it is not determined that the operation is performed to the operated member 51 as long as the contact or approach of the finger 30 with respect to the detection electrode 523 disposed between the first detection area 511 and the second detection area 512 is detected. For example, when the finger 30 performing an operation with respect to the second detection area 512 unintentionally contacts or approaches the first detection area 511, it accompanies contact or approach with respect to the detection electrode 523. Accordingly, it is possible to suppress the occurrence of a situation that the contact or approach is detected as an operation with respect to the first detection area 111. Accordingly, it is possible to improve the operability of the electrostatic sensor equipped with the operated member having a plurality of detection areas.

As illustrated in FIG. 6, the operated member 51 may be equipped with an insulating portion 515. The insulating portion 515 electrically insulates each of the first detection area 511 and the second detection area 512 from the detection electrode 523.

According to such a configuration, the electrical reaction of each of the first detection area 511 and the second detection area 512 with respect to the contact or approach of the finger 30 can be easily distinguished from the electrical reaction of the detection electrode 523 with respect to the contact or approach of the finger 30. Accordingly, even if it is possible to secure the above-described function of the detection electrode 523, it is also possible to suppress the degradation of the operability with respect to each of the first detection area 511 and the second detection area 512.

The processor 542 having each function described above can be implemented by a general-purpose microprocessor operating in cooperation with a general-purpose memory. Examples of the general-purpose microprocessor include a CPU, an MPU, and a GPU. Examples of the general-purpose memory include a ROM and a RAM. In this case, a computer program for executing the above-described processing can be stored in the ROM. The ROM is an example of a non-transitory computer-readable medium having recorded a computer program. The general-purpose microprocessor designates at least a part of the program stored in the ROM, loads the program on the RAM, and executes the processing described above in cooperation with the RAM. The above-mentioned computer program may be pre-installed in a general-purpose memory, or may be downloaded from an external server via a communication network and then installed in the general-purpose memory. In this case, the external server is an example of the non-transitory computer-readable medium having stored a computer program.

The processor 542 may be implemented by a dedicated integrated circuit capable of executing the above-described computer program, such as a microcontroller, an ASIC, and an FPGA. In this case, the above-described computer program is pre-installed in the storage element included in the dedicated integrated circuit. The memory element is an example of a non-transitory computer-readable medium in which a computer program is stored. The processor 542 may also be implemented by a combination of a general-purpose microprocessor and a dedicated integrated circuit.

The above embodiments are merely illustrative for facilitating understanding of the presently disclosed subject matter. The configuration according to the above embodiment can be appropriately modified or improved without departing from the gist of the presently disclosed subject matter.

In the above embodiment, the operated member 51 has two detection areas. However, the number of the detection areas may be three or more. The position, shape, size, and type of operation that can be accepted of each detection area in the operated member 51 can be appropriately determined according to the function of the controlled device 40 to be controlled.

As an example, as illustrated in FIG. 8, the operated member 51 may have a third detection area 513. The third detection area 513 is adjacent to the first detection area 511. In this case, a detection electrode 524 is disposed between the first detection area 511 and the third detection area 513. The processing described with reference to the detection electrode 523 is also applied to the detection electrode 524 as well.

In the above embodiment, the absolute value of the detected electrostatic capacitance is used for comparison with the threshold value in order to determine whether an operation is performed to the detection area of the operated member 51. However, the determination as to whether the operation with respect to the detection area is performed may be made based on an amount of change from a reference electrostatic capacitance that can be constantly changed according to the state of the operated member 51. In this case, a threshold value defined for the amount of change is used.

In the above embodiment, the electrostatic capacitance between the operated member 51 and the finger 30 of the occupant is detected. As long as a change in the electrostatic capacitance caused by an operation performed to the operated member 51 can be detected, the operation may be performed with another body part, or with clothing or a tool interposed between the body part and the operated member 51. Other body parts, and objects such as the clothing and the tool are also examples of the operating item.

In this case, as illustrated in FIG. 8, it is preferable that a sum of a size of each detection area and a surface area of the insulating portion 515 is larger than a contact area A assumed for the operating item performing an operation with respect to the operated member 51. According to such a configuration, even if it is possible to suppress the occurrence of a situation that an operation performed to one of the detection areas is made due to unintentional contact or approach of the operating item to the one of the detection areas, it is also possible to suppress the degradation of the operability with respect to the one of the detection areas. This advantage becomes more remarkable as at least one of the size of each detection area and the distance between the adjacent detection areas becomes smaller.

The electrostatic sensor 50 may be installed in a mobile entity other than the vehicle 20. Examples of the mobile entity include railways, aircrafts, and ships. The mobile entity may not require a driver. The electrostatic sensor 50 may be installed in a mobile device capable of being carried by a user. A mobile device is also an example of the mobile entity. When the electrostatic sensor 50 is provided in such a mobile entity, a part of the user's body tends to contact or approach an unintended detection area due to the movement or vibration of the mobile entity. Accordingly, the utility of the electrostatic sensor 50 having the configuration as described above is further enhanced.

The electrostatic sensor 50 need not be installed in a mobile entity. As long as the operation of the controlled device 40 can be controlled through an operation performed to the operated member 51, the illustrated configuration can be applied to any application, such as a stationary device, a building such as a house or a facility.

The present application is based on Japanese Patent Application No. 2020-095691 filed on Jun. 1, 2020, the entire contents of which are incorporated herein by reference.

What is claimed is:

1. An electrostatic sensor, comprising:
a detection device configured to detect an electrostatic capacitance between an operated member having a plurality of detection areas and an electrode having areas associated with the detection areas respectively; and
a control device configured to determine whether an operation is performed to each of the detection areas based on whether the electrostatic capacitance exceeds a threshold value,
wherein at least one of the detection areas has a first area and a second area;
wherein the second area is located between the first area and another one of the detection areas; and
wherein the control device determines that an operation is not performed to the at least one detection area having the first area and the second area in a case where the electrostatic capacitance detected for the second area exceeds the threshold value.

2. An electrostatic sensor, comprising:
a detection device configured to detect an electrostatic capacitance between an operated member having a plurality of detection areas and an electrode having areas associated with the detection areas respectively; and
a control device configured to determine whether an operation is performed to each of the detection areas based on whether the electrostatic capacitance exceeds a threshold value,
wherein at least one of the detection areas has a first area and a second area;
wherein the second area is located between the first area and another one of the detection areas; and
wherein the control device determines that an operation is performed to the at least one detection area having the first area and the second area in a case where the electrostatic capacitance detected for the first area exceeds the threshold value.

3. The electrostatic sensor according to claim 2, wherein even if the electrostatic capacitance detected for the second area exceeds the threshold value, the control device determines that an operation is performed to the at least one detection area having the first area and the second area as long as the electrostatic capacitance detected for the first area exceeds the threshold value.

4. The electrostatic sensor according to claim 1, wherein a size of the first area is larger than a size of the second area.

5. The electrostatic sensor according to claim 1, wherein the size of the first area is larger than a contact area assumed for an operating item that performs an operation with respect to the operated member.

6. The electrostatic sensor according to claim 1, being configured to be installed in a mobile entity.

7. The electrostatic sensor according to claim 2, wherein a size of the first area is larger than a size of the second area.

8. The electrostatic sensor according to claim 2, wherein the size of the first area is larger than a contact area assumed for an operating item that performs an operation with respect to the operated member.

9. The electrostatic sensor according to claim 2, being configured to be installed in a mobile entity.

10. A control device configured to control an operation of an electrostatic sensor equipped with an operated member having a plurality of detection areas, comprising:
a reception interface configured to receive detection information corresponding to an electrostatic capacitance between the operated member and an electrode having areas associated with the detection areas respectively; and
a processor configured to determine whether an operation is performed to each of the detection areas based on whether the electrostatic capacitance exceeds a threshold value,
wherein at least one of the detection areas has a first area and a second area;
wherein the second area is located between the first area and another one of the detection areas; and
wherein the processor determines that an operation is not performed to the at least one detection area having the first area and the second area in a case where the electrostatic capacitance detected for the second area exceeds the threshold value.

11. A control device configured to control an operation of an electrostatic sensor equipped with an operated member having a plurality of detection areas, comprising:
a reception interface configured to receive detection information corresponding to an electrostatic capacitance between the operated member and an electrode having areas associated with the detection areas respectively; and
a processor configured to determine whether an operation is performed to each of the detection areas based on whether the electrostatic capacitance exceeds a threshold value,
wherein at least one of the detection areas has a first area and a second area;
wherein the second area is located between the first area and another one of the detection areas; and
wherein the processor determines that an operation is performed to the at least one detection area having the first area and the second area in a case where the electrostatic capacitance detected for the first area exceeds the threshold value.

12. A non-transitory computer-readable medium having stored a computer program adapted to be executed by a processor of a control device configured to control an operation of an electrostatic sensor equipped with an operated member having a plurality of detection areas, wherein at least one of the detection areas has a first area and a second area, and wherein the second area is located between the first area and another one of the detection areas, the computer program is configured to cause, when executed, the control device to:
receive detection information corresponding to an electrostatic capacitance between the operated member and an electrode having areas associated with the detection areas respectively;
determine whether an operation is performed to each of the detection areas based on whether the electrostatic capacitance exceeds a threshold value; and
determine that an operation is not performed to the at least one detection area having the first area and the second area in a case where the electrostatic capacitance detected for the second area exceeds the threshold value.

13. A non-transitory computer-readable medium having stored a computer program adapted to be executed by a processor of a control device configured to control an operation of an electrostatic sensor equipped with an operated member having a plurality of detection areas, wherein at least one of the detection areas has a first area and a second area, and wherein the second area is located between the first area and another one of the detection areas, the computer program is configured to cause, when executed, the control device to:
receive detection information corresponding to an electrostatic capacitance between the operated member and an electrode having areas associated with the detection areas respectively;
determine whether an operation is performed to each of the detection areas based on whether the electrostatic capacitance exceeds a threshold value; and
determine that an operation is performed to the at least one detection area having the first area and the second area in a case where the electrostatic capacitance detected for the first area exceeds the threshold value.

14. An electrostatic sensor, comprising:
a detection device configured to detect an electrostatic capacitance between an operated member having a plurality of detection areas and an electrode having areas associated with the detection areas respectively; and
a control device configured to determine whether an operation is performed to each of the detection areas based on whether the electrostatic capacitance exceeds a threshold value,
wherein the detection device detects contact or approach of an operating item with respect to a detection electrode located between the contact areas; and
wherein the control device determines that an operation is not performed to the operated member in a case where the contact or approach of the operating item with respect to the detection electrode is detected.

15. The electrostatic sensor according to claim 14, wherein the operated member has an insulating portion electrically insulating the detection electrode from the detection areas.

16. The electrostatic sensor according to claim 15, wherein a sum of a size of one of the detection areas and a surface area of the insulating portion is larger than a contact area assumed for the operating item.

17. The electrostatic sensor according to claim 14, being configured to be installed in a mobile entity.

18. A control device configured to control an operation of an electrostatic sensor equipped with an operated member having a plurality of detection areas, comprising:
a reception interface configured to receive first detection information corresponding to an electrostatic capacitance between the operated member and an electrode having areas associated with the detection areas respectively; and
a processor configured to determine whether an operation is performed to each of the detection areas based on whether the electrostatic capacitance corresponding to the first detection information exceeds a threshold value,
wherein the reception interface receives second detection information indicative of contact or approach of an operating item with respect to a detection electrode located between the contact areas; and
wherein the processor determines that an operation is not performed to the operated member in a case where the reception interface receives the second detection information.

19. A non-transitory computer-readable medium having stored a computer program adapted to be executed by a processor of a control device configured to control an operation of an electrostatic sensor equipped with an operated member having a plurality of detection areas, the computer program is configured to cause, when executed, the control device to:
receive first detection information corresponding to an electrostatic capacitance between the operated member and an electrode having areas associated with the detection areas respectively;
receive second detection information indicative of contact or approach of an operating item with respect to a detection electrode located between the contact areas;
determine whether an operation is performed to each of the detection areas based on whether the electrostatic capacitance corresponding to the first detection information exceeds a threshold value; and
determine that an operation is not performed to the operated member in a case where the reception interface receives the second detection information.
